(19) United States
(12) Patent Application Publication
(10) Pub. No.: US 2018/0101093 A1
(43) Pub. Date: Apr. 12, 2018

(54) MANUFACTURE METHOD OF NANO-IMPRINT LITHOGRAPHY TEMPLATE AND NANO-IMPRINT LITHOGRAPHY TEMPLATE

(71) Applicant: Shenzhen China Star Optoelectronics Technology Co., Ltd., Shenzhen City (CN)

(72) Inventors: Lixuan Chen, Shenzhen City (CN); Yungjui Lee, Shenzhen City (CN)

(21) Appl. No.: 15/106,313

(22) PCT Filed: May 13, 2016
(86) PCT No.: PCT/CN2016/081970

§ 371 Date: Jun. 19, 2016

(30) Foreign Application Priority Data
Apr. 21, 2016 (CN) 201610255462.7

(51) Int. Cl. G03F 7/00

(52) U.S. Cl. CPC G03F 7/0002; G03F 7/0007; G03F 7/0017

(57) ABSTRACT

The present invention provides a manufacture method of a nano-imprint lithography template and a nano-imprint lithography template. In the manufacture method of the nano-imprint lithography template, first, the soft membrane having a nanowire gate structure is wrapped on the outer circumferential surface of the cylindric hard roller to form the nanowire gate structure film layer to obtain the temporary roller. Then, the low melting point solder alloy is utilized to form the structure hardened layer on the outer circumferential surface of the temporary roller along the nanowire gate structure of the nanowire gate structure film layer to obtain the nano-imprint lithography template having the nanowire gate structure. By forming the hard structure hardened layer on the soft nanowire gate structure for hardening the soft nanowire gate structure, the issue that the hardness of the micro structure material itself in the imprint procedure is not enough is overcame.

### FIELD OF THE INVENTION

The present invention relates to a display technology field, and more particularly to a manufacture method of a nano-imprint lithography template and a nano-imprint lithography template.

### BACKGROUND OF THE INVENTION

Nano-imprint Lithography (NIL) technology solves the difficult problem of the traditional photolithography in the feature size reduction process, and possesses the properties of high resolution, low cost and high production efficiency. Since the propose in 1995, the nano-imprint Lithography has already been evolved out many kinds of imprint skills, and widely applied in field of the semiconductor manufacture, Microelectromechanical (Systems MEMS), biochip and biomedicine. The basic idea of the NIL technology is to transfer the pattern onto the corresponding substrate with the template. The transfer medium is a polymer film which is very thin in general, and hardens the structure with hot pressing or irradiation to preserve the transferred pattern. The entire process includes two procedures of imprint and pattern transfer. According to the imprint method, NIL mainly can be categorized into three photolithography skills of Hot embossing, UV solidification and Micro contact printing (uCP).

For the kinds of elements which require the polarizers, such as the LCD, OLED, the traditional polarizer is the iodine based polarizer of organic material and the dye based polarizer. With the development of the Nano-imprint Lithography technology, people have already tried to manufacture the metal gate structure of small size for realizing the polarization function to the light in the visible light wavelength range. Because the absorption of the metal gate structure itself to the light is very small, by reflecting one polarization of the natural light and allowing another polarization passing through, the reflected light can be recycled and utilized again with polarization rotation, and it has great potential in the liquid crystal display.

In the process and method of manufacturing the metal gate structure polarizer structure with NIL technology, there are still lots of issues, such as that the procedure of the pattern transfer always occupies a mass of time, and meanwhile, kinds of defaults in the manufacture process ultimately have the influence which is more serious to the gate formation.

### SUMMARY OF THE INVENTION

An objective of the present invention is to provide a manufacture method of a nano-imprint lithography template, the low melting point solder alloy is utilized to form a hard structure hardened layer on the soft nanowire gate structure for overcoming the issue that the hardness of the micro structure material itself is not enough to make the roll to roll micro structure imprint lithography, and particularly the nano-imprint lithography become the possible portion of the practical art, and thus to raise the manufacture efficiency of the gate polarizer.

Another objective of the present invention is to provide a nano-imprint lithography template, comprising a structure hardened layer of had alloy material on the soft nanowire gate structure. The roll to roll method can be utilized to manufacture the gate polarizer, and thus to raise the manufacture efficiency of the gate polarizer.

For realizing the aforesaid objectives, the present invention first provides a manufacture method of a nano-imprint lithography template, comprising steps of:

step 1, providing a cylindric hard roller;

step 2, providing a membrane having a nanowire gate structure, and wrapping the membrane on an outer circumferential surface of the hard roller to form a nanowire gate structure film layer to obtain a temporary roller;

step 3, providing low melting point solder alloy, and heating the low melting point solder alloy to a liquid state, and immersing the temporary roller obtained in the step 2 in the low melting point solder alloy liquid, or coating one layer of the low melting point solder alloy liquid on the temporary roller which is heated, and after cooling, one structure hardened layer is formed on an outer circumferential surface of the temporary roller along the nanowire gate structure of the nanowire gate structure film layer to obtain the nano-imprint lithography template having the nanowire gate structure.

The low melting point solder alloy provided in the step 3 is alloy material, of which a melting temperature is lower than 300° C.

The membrane provided in the step 2 is organic material, of which a melting temperature is higher than the melting temperature of the low melting point solder alloy.

The obtain nano-imprint lithography template comprises a plurality of gating grooves which are periodically arranged, and both a width of the gating groove and a distance of two adjacent gating grooves are smaller than 150 nm.

Material of the membrane provided in the step 2 is PMMA, POM, PBT, PET, PC, PE, PEEK, PP, PS or PVDC.

The present invention further provides a nano-imprint lithography template, comprising a cylindric hard roller, a nanowire gate structure film layer located on an outer circumferential surface of the hard roller and a structure hardened layer covering the nanowire gate structure film layer;

the nanowire gate structure film layer is a membrane having a nanowire gate structure;

material of the structure hardened layer is low melting point solder alloy, and the structure hardened layer is formed along the nanowire gate structure of the nanowire gate structure film layer.

The low melting point solder alloy is alloy material, of which a melting temperature is lower than 300° C.

The membrane employed to be the nanowire gate structure film layer is organic material, of which a melting temperature is higher than a melting temperature of the low melting point solder alloy of the structure hardened layer.

The nano-imprint lithography template comprises a plurality of gating grooves which are periodically arranged, and both a width of the gating groove and a distance of two adjacent gating grooves are smaller than 150 nm.

Material of the membrane employed to be the nanowire gate structure film layer is PMMA, POM, PBT, PET, PC, PE, PEEK, PP, PS or PVDC.

The present invention further provides a manufacture method of a nano-imprint lithography template, comprising steps of:

step 1, providing a cylindric hard roller;

step 2, providing a membrane having a nanowire gate structure, and wrapping the membrane on an outer circumferential surface of the hard roller to form a nanowire gate structure film layer to obtain a temporary roller;

step 3, providing low melting point solder alloy, and heating the low melting point solder alloy to a liquid state, and immersing the temporary roller obtained in the step 2 in the low melting point solder alloy liquid, or coating one layer of the low melting point solder alloy liquid on the temporary roller which is heated, and after cooling, one structure hardened layer is formed on an outer circumferential surface of the temporary roller along the nanowire gate structure of the nanowire gate structure film layer to obtain the nano-imprint lithography template having the nanowire gate structure;

wherein the low melting point solder alloy provided in the step 3 is alloy material, of which a melting temperature is lower than 300° C.;

wherein the membrane provided in the step 2 is organic material, of which a melting temperature is higher than the melting temperature of the low melting point solder alloy;

The benefits of the present invention are: in the manufacture method of the nano-imprint lithography template according to the present invention, first, the soft membrane having a nanowire gate structure is wrapped on the outer circumferential surface of the cylindric hard roller to form the nanowire gate structure film layer to obtain the temporary roller. Then, the low melting point solder alloy is utilized to form the structure hardened layer on the outer circumferential surface of the temporary roller along the nanowire gate structure of the nanowire gate structure film layer to obtain the nano-imprint lithography template having the nanowire gate structure. By forming the hard structure hardened layer on the soft nanowire gate structure for hardening the soft nanowire gate structure, the issue that the hardness of the micro structure material itself in the imprint procedure is not enough is overcame to make the roll to roll micro structure imprint lithography, and particularly the nano-imprint lithography become the possible portion of the practical art, and thus to raise the manufacture efficiency of the gate polarizer. The nano-imprint lithography template of the present invention appears to be cylindric as a whole, and comprises a structure hardened layer of had alloy material on the soft nanowire gate structure. The roll to roll method can be utilized to manufacture the gate polarizer, and thus to raise the manufacture efficiency of the gate polarizer.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of a manufacture method of a nano-imprint lithography template according to the present invention;

FIG. 2 is a diagram of the step 1 in the manufacture method of the nano-imprint lithography template according to the present invention;

FIG. 3 is a diagram of the step 2 in the manufacture method of the nano-imprint lithography template according to the present invention;

FIG. 4 is a diagram of a nanowire gate structure provided in the step 2 in the manufacture method of the nano-imprint lithography template according to the present invention;

FIG. 5 is a diagram of the step 3 in the manufacture method of the nano-imprint lithography template according to the present invention and a three dimensional structure diagram of a nano-imprint lithography template according to the present invention;

FIG. 6 is a diagram of a nanowire gate structure on the nano-imprint lithography template according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

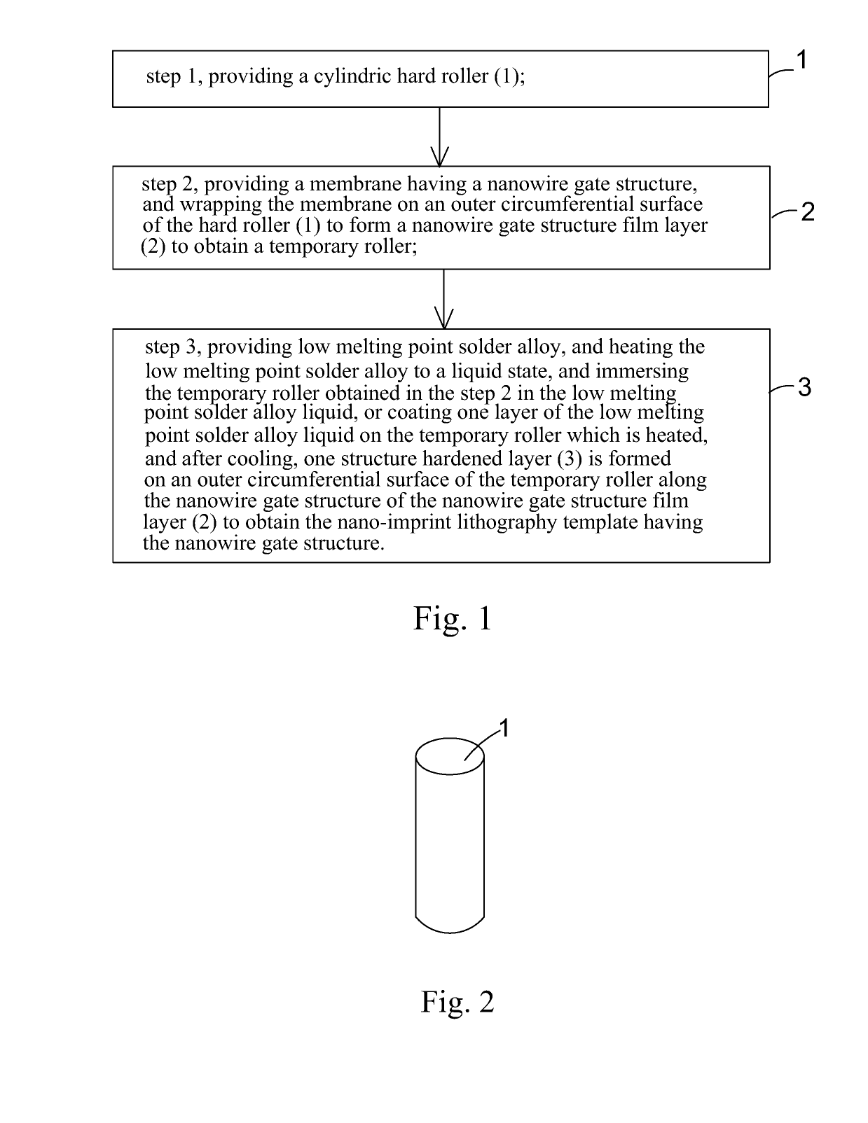

Please refer to FIG. 1. The present invention provides a manufacture method of a nano-imprint lithography template, comprising steps of:

step 1, as shown in FIG. 2, providing a cylindric hard roller 1.

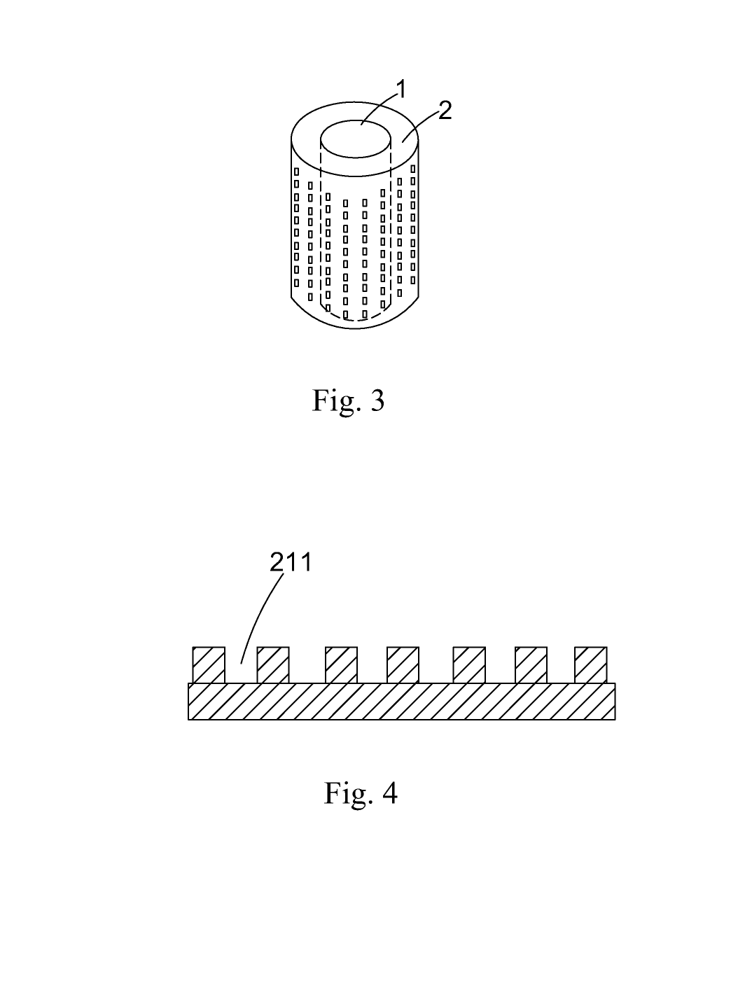

step 2, as shown in FIG. 3, providing a membrane having a nanowire gate structure, and wrapping the membrane on an outer circumferential surface of the hard roller 1 to form a nanowire gate structure film layer 2 to obtain a temporary roller.

Specifically, the membrane provided in the step 2 is organic material. As shown in FIG. 4, it comprises a plurality of initial gating grooves 211 which are periodically arranged thereon, and is employed to construct the initial micro structure of the nano-imprint lithography template to be formed. Particularly, the property of the membrane is that the gate period of the nanowire gate structure and the gate height are both slightly larger than the required values. Accordingly, the allowance is saved for the alloy material wrapping thereon in the following, and the temperature resistance thereof ensures that it can at least stand the high temperature more than 100° C.

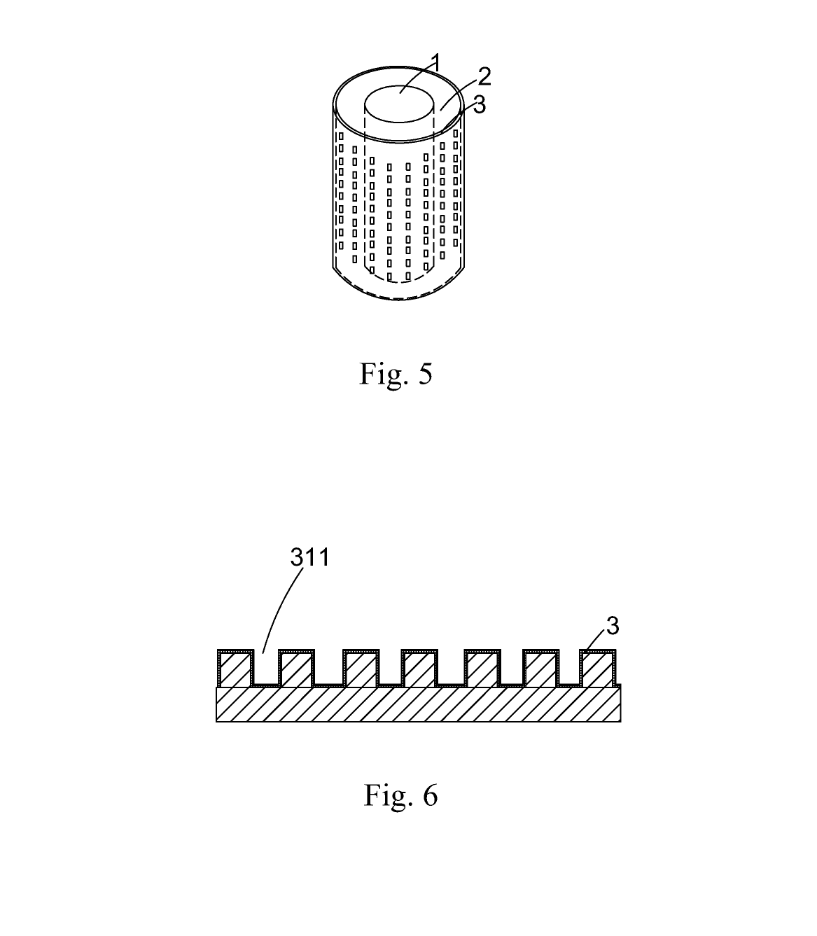

step 3, as shown in FIG. 5, providing low melting point solder alloy, and heating the low melting point solder alloy to a liquid state, and immersing the temporary roller obtained in the step 2 in the low melting point solder alloy liquid, or coating one layer of the low melting point solder alloy liquid on the temporary roller which is heated, and after cooling, one structure hardened layer 3 is formed on an outer circumferential surface of the temporary roller along the nanowire gate structure of the nanowire gate structure film layer 2 to obtain the nano-imprint lithography template having the nanowire gate structure.

Specifically, the low melting point solder alloy provided in the step 3 can be 8.3Sn44.7Bi22.6Pb5.3Cd19.1In, in which the component and the weight percentage of the raw material thereof is: tin (Sn) 8.3%, bismuth (Bi) 44.7%, plumbum (Pb) 22.6%, chromium (Cd) 5.3%, indium (In) 19.1%, or can be other low melting point solder alloy, of which has indium or tin and a melting temperature is lower than 300° C., such as 100In, 66.3In33.7Bi, 51Tn32.5Bi6.5Sn, 57Bi26In17Sn, 54.02Bi29.68In16.3Sn, 67Bi33In, 50In50Sn, 52Sn48In, 58Bi42Sn, 97In3Ag, 58Bi42Sn, 99.3In0.7Ga, 95In5Bi, 99.4In0.6Ga, 99.6In0.4Ga, 99.5In0.5Ga, 60Sn40Bi, 100Sn, 95Sn5Sb.

Specifically, the nano-imprint lithography template obtained in the step 3 comprises a plurality of gating grooves 311 which are periodically arranged, and both a width of the gating groove 311 and a distance of two adjacent gating grooves are smaller than 150 nm.

Particularly, material of the membrane provided in the step 2 can be selected from organic material, such as PMMA (polymethylmethacrylate), POM (polyoxymethylene), PBT (polybutylene terephthalate), PET (polyethylene glycol terephthalate), PC (polycarbonate), PE (polyethylene), PEEK (polyetheretherketone), PP (polypropylene), PS (polystyrene) and PVDC (polyvinylidine chloride). However, the temperature resistance property of the selected membrane must satisfy that it can stand the temperature as the low melting point solder alloy selected in the step 3 is in a liquid state. Namely, the membrane in the step 3 has to be ensured not to deform. Therefore, the melting temperature of the membrane provided in the step 2 must be higher than the melting temperature of the low melting point solder alloy.

As shown in FIG. 6, in the manufacture method of the nano-imprint lithography template according to the present invention, the low melting point solder alloy is utilized to form a hard structure hardened layer on the soft nanowire gate structure for hardening the soft nanowire gate structure for overcoming the issue that the hardness of the micro structure material itself in the imprint procedure is not enough to make the roll to roll micro structure imprint lithography, and particularly the nano-imprint lithography become the possible portion of the practical art, and thus to raise the manufacture efficiency of the gate polarizer.

Specifically, the specific procedure of employing the nano-imprint lithography template manufactured by the present invention to manufacture the gate polarizer with roll to roll is: the roller is employed to transport the substrate, and coating light curable photoresist or heat curable photoresist to form the photoresist layer. The cylindric nano-imprint lithography template of the present invention is used, and the nano-imprint lithography template comprises the structure hardened layer, on which the hardness of the micro structure is larger than the hardness of the photoresist layer. The nano-imprint lithography template is rotated to imprint on the photoresist layer of the light curable photoresist or the heat curable photoresist, and meanwhile, UV light irradiation or heating is implemented to harden the photoresist layer for accomplishing the transfer procedure of the nano morphology. The planar imprint procedure is converted into the three dimensional rolling process. With the UV light irradiation or heating, the production efficiency of the gate polarizer is raised. Similarly, except the UV imprint and the Hot embossing, the cylindric nano-imprint lithography template also can be similarly applied in the procedure of other mechanical nano-imprint formations. Because the hardness of the nano-imprint lithography template is higher than the bright adhesive which is imprinted. Then, the imprint formation can be done with the mechanical stress and the transfer procedure of the nano morphology can be accomplished.

Please refer to FIG. 5. The present invention further provides a nano-imprint lithography template comprising a cylindric hard roller 1, a nanowire gate structure film layer 2 located on an outer circumferential surface of the hard roller 1 and a structure hardened layer 3 covering the nanowire gate structure film layer 2;

the nanowire gate structure film layer 2 is a membrane having a nanowire gate structure;

material of the structure hardened layer 3 is low melting point solder alloy, and is formed along the nanowire gate structure of the nanowire gate structure film layer 2. Thus, the nanowire gate structure of the nano-imprint lithography template which is relatively harder than the nanowire gate structure of the nanowire gate structure film layer 2 is formed.

Specifically, the low melting point solder alloy employed to be the structure hardened layer 3 can be 8.3Sn44.7Bi22.6Pb5.3Cd19.1In, in which the component and the weight percentage of the raw material thereof is: tin (Sn) 8.3%, bismuth (Bi) 44.7%, plumbum (Pb) 22.6%, chromium (Cd) 5.3%, indium (In) 19.1%, and certainly can be other low melting point solder alloy, of which has indium or tin and a melting temperature is lower than 300° C., such as 100In, 66.3In33.7Bi, 51Tn32.5Bi6.5Sn, 57Bi26In17Sn, 54.02Bi29.68In16.3Sn, 67Bi33In, 501n50Sn, 52Sn48In, 58Bi42Sn, 97In3Ag, 58Bi42Sn, 99.3In0.7Ga, 95In5Bi, 99.4In0.6Ga, 99.6In0.4Ga, 99.5In0.5Ga, 60Sn40Bi, 100Sn, 95Sn5Sb.

Specifically, the nano-imprint lithography template comprises a plurality of gating grooves 311 which are periodically arranged, and both a width of the gating groove 311 and a distance of two adjacent gating grooves are smaller than 150 nm.

Specifically, the membrane employed to be the nanowire gate structure film layer 2 is organic material, of which a melting temperature is higher than a melting temperature of the low melting point solder alloy of the structure hardened layer 3. The material of the membrane specifically can be selected from the nanowire gate structure film layer can be selected from organic material such as PMMA, POM, PBT, PET, PC, PE, PEEK, PP, PS and PVDC.

In conclusion, in the manufacture method of the nano-imprint lithography template according to the present invention, first, the soft membrane having a nanowire gate structure is wrapped on the outer circumferential surface of the cylindric hard roller to form the nanowire gate structure film layer to obtain the temporary roller. Then, the low melting point solder alloy is utilized to form the structure hardened layer on the outer circumferential surface of the temporary roller along the nanowire gate structure of the nanowire gate structure film layer to obtain the nano-imprint lithography template having the nanowire gate structure. By forming the hard structure hardened layer on the soft nanowire gate structure for hardening the soft nanowire gate structure, the issue that the hardness of the micro structure material itself in the imprint procedure is not enough is overcame to make the roll to roll micro structure imprint lithography, and particularly the nano-imprint lithography become the possible portion of the practical art, and thus to raise the manufacture efficiency of the gate polarizer. The nano-imprint lithography template of the present invention appears to be cylindric as a whole, and comprises a structure hardened layer of had alloy material on the soft nanowire gate structure. The roll to roll method can be utilized to manufacture the gate polarizer, and thus to raise the manufacture efficiency of the gate polarizer.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a nano-imprint lithography template, comprising steps of:
step 1, providing a cylindric hard roller;
step 2, providing a membrane having a nanowire gate structure, and wrapping the membrane on an outer circumferential surface of the hard roller to form a nanowire gate structure film layer to obtain a temporary roller;
step 3, providing low melting point solder alloy, and heating the low melting point solder alloy to a liquid state, and immersing the temporary roller obtained in the step 2 in the low melting point solder alloy liquid, or coating one layer of the low melting point solder alloy liquid on the temporary roller which is heated, and after cooling, one structure hardened layer is formed on an outer circumferential surface of the temporary roller along the nanowire gate structure of the nanowire gate structure film layer to obtain the nano-imprint lithography template having the nanowire gate structure.

2. The manufacture method of the nano-imprint lithography template according to claim 1, wherein the low melting point solder alloy provided in the step 3 is alloy material, of which a melting temperature is lower than 300° C.

3. The manufacture method of the nano-imprint lithography template according to claim 1, wherein the membrane provided in the step 2 is organic material, of which a melting temperature is higher than the melting temperature of the low melting point solder alloy.

4. The manufacture method of the nano-imprint lithography template according to claim 1, wherein the obtain nano-imprint lithography template comprises a plurality of gating grooves which are periodically arranged, and both a width of the gating groove and a distance of two adjacent gating grooves are smaller than 150 nm.

5. The manufacture method of the nano-imprint lithography template according to claim 3, wherein material of the membrane provided in the step 2 is PMMA, POM, PBT, PET, PC, PE, PEEK, PP, PS or PVDC.

6. A nano-imprint lithography template, comprising a cylindric hard roller, a nanowire gate structure film layer located on an outer circumferential surface of the hard roller and a structure hardened layer covering the nanowire gate structure film layer;
the nanowire gate structure film layer is a membrane having a nanowire gate structure;
material of the structure hardened layer is low melting point solder alloy, and the structure hardened layer is formed along the nanowire gate structure of the nanowire gate structure film layer.

7. The nano-imprint lithography template according to claim 6, wherein the low melting point solder alloy is alloy material, of which a melting temperature is lower than 300° C.

8. The nano-imprint lithography template according to claim 6, wherein the membrane employed to be the nanowire gate structure film layer is organic material, of which a melting temperature is higher than a melting temperature of the low melting point solder alloy of the structure hardened layer.

9. The nano-imprint lithography template according to claim 6, wherein the nano-imprint lithography template comprises a plurality of gating grooves which are periodically arranged, and both a width of the gating groove and a distance of two adjacent gating grooves are smaller than 150 nm.

10. The nano-imprint lithography template according to claim 8, wherein material of the membrane employed to be the nanowire gate structure film layer is PMMA, POM, PBT, PET, PC, PE, PEEK, PP, PS or PVDC.

11. A manufacture method of a nano-imprint lithography template, comprising steps of:
step 1, providing a cylindric hard roller;
step 2, providing a membrane having a nanowire gate structure, and wrapping the membrane on an outer circumferential surface of the hard roller to form a nanowire gate structure film layer to obtain a temporary roller;
step 3, providing low melting point solder alloy, and heating the low melting point solder alloy to a liquid state, and immersing the temporary roller obtained in the step 2 in the low melting point solder alloy liquid, or coating one layer of the low melting point solder alloy liquid on the temporary roller which is heated, and after cooling, one structure hardened layer is formed on an outer circumferential surface of the temporary roller along the nanowire gate structure of the nanowire gate structure film layer to obtain the nano-imprint lithography template having the nanowire gate structure;
wherein the low melting point solder alloy provided in the step 3 is alloy material, of which a melting temperature is lower than 300° C.;
wherein the membrane provided in the step 2 is organic material, of which a melting temperature is higher than the melting temperature of the low melting point solder alloy;

12. The manufacture method of the nano-imprint lithography template according to claim 11, wherein the obtain nano-imprint lithography template comprises a plurality of gating grooves which are periodically arranged, and both a width of the gating groove and a distance of two adjacent gating grooves are smaller than 150 nm.

13. The manufacture method of the nano-imprint lithography template according to claim 11, wherein material of the membrane provided in the step 2 is PMMA, POM, PBT, PET, PC, PE, PEEK, PP, PS or PVDC.
